(19) United States
(12) Patent Application Publication
(10) Pub. No.: US 2009/0166650 A1
(43) Pub. Date: Jul. 2, 2009

(54) LIGHT-EMITTING DEVICE OF GROUP III NITRIDE-BASED SEMICONDUCTOR AND MANUFACTURING METHOD THEREOF

(75) Inventors: SHIH CHENG HUANG, HSINCHU CITY (TW); PO MIN TU, CHIAYI COUNTY (TW); YING CHAO YEH, TAIPEI COUNTY (TW); WEN YU LIN, TAICHUNG COUNTY (TW); PENG YI WU, TAICHUNG CITY (TW); CHIH PENG HSU, TAINAN COUNTY (TW); SHIH HSIUNG CHAN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/343,984

(22) Filed: Dec. 24, 2008

(30) Foreign Application Priority Data
Dec. 28, 2007 (TW) 096150701

(51) Int. Cl. H01L 33/00; H01L 21/02; H01L 21/04

(52) U.S. Cl. 257/94; 257/103; 438/46; 438/47; 257/E33.001; 257/E21.002; 257/E21.04

(57) ABSTRACT

A light-emitting device of Group III nitride-based semiconductor comprises a substrate, a first Group III nitride layer and a second Group III nitride layer. The substrate comprises a first surface and a plurality of convex portions protruding from the first surface. Each convex portion is surrounded by a part of the first surface. The first Group III nitride layer is jointly formed by lateral growth starting at top surfaces of the convex portions. The second Group III nitride layer is formed on the first surface, wherein a thickness of the second Group III nitride layer is less than a height of the convex portion. Moreover, the first Group III nitride layer and the second Group III nitride layer are made of a same material.

### BACKGROUND OF THE INVENTION

1. Field of the Invention

The present invention relates to a light emitting device (LED) of Group III nitride-based semiconductor and the manufacturing method thereof, and relates more particularly to a light-emitting device of Group III nitride-based semiconductor with high light extraction efficiency and the manufacturing method thereof.

2. Description of the Related Art

With widespread applications of light emitting devices in different products, the semiconductor materials used in making blue LEDs have in recent years been the focus of research in the opto-electronic materials and is device area. To date, blue LEDs are made of zinc selenide (ZnSe) material, silicon carbide (SiC) material and indium gallium nitride (InGaN) material, all of which are wide band gap semiconductors, with band gap values over approximately 2.6 eV. Gallium nitride is a direct, wide band gap semiconductor, and therefore it can produce high intensity of light and have a longer lifetime than ZnSe.

In order to increase the light intensity of an LED, experts in the field of opto-electronic materials and devices have developed several approaches. For example, one approach related to epitaxial technology is to try to minimize the dislocation density of a light-emitting layer while increasing donor and acceptor concentrations as much as possible. The increase of acceptor concentration in a light-emitting layer (active layer) is difficult, and more difficult in a wide band gap gallium nitride layer. In the meanwhile, due to the substantially large lattice match between a sapphire substrate and gallium nitride material, it's not easy to achieve a breakthrough in technology to minimize the dislocation density.

FIG. 1 is a cross-sectional view illustrating a semiconductor light-emitting device disclosed in U.S. Pat. No. 6,870,191. The semiconductor light-emitting device 10 comprises a sapphire substrate 11, an N-type semiconductor layer 12, an active layer 13 and a P-type semiconductor layer 14. A plurality of recesses 15 arranged in parallel are formed on the sapphire substrate 11, which is a C-face (0001) oriented sapphire substrate, and the shapes of the recesses 15 for preventing the growth of defects in the N-type semiconductor layer 12 are shapes having, as component sides, lines that cross a plane approximately parallel to the stably growing face (i.e. M face, (1 1̅ 0 0)) of N-type semiconductor layer 12 on the sapphire substrate 11.

FIGS. 2A-2F are schematic diagrams illustrating an epitaxial process for forming an N-type semiconductor layer of FIG. 1 on a sapphire substrate. In contrast to the recesses on the sapphire substrate 12, the higher portion is deemed a base surface 16. When an N-type semiconductor layer 11 starts being grown on the sapphire substrate 11, it is grown accumulatively on the base surface 16 and the surfaces of the recesses 15, but the growth rate thereof on sides of the recesses 15 is relatively slow. Referring to FIGS. 2D-2F, when the N-type semiconductor layer grown from the bottom of the recesses 15 and the N-type semiconductor layer grown from the base surface 16 meet, the growth rate of the N-type semiconductor layer becomes higher. Finally, a flat voidless N-type semiconductor layer having better crystallinity is formed.

However, with larger contact area between two layers having different lattice constants and thicker accumulation of the atomic layers, the dislocation density caused by lattice mismatch becomes denser. Because the semiconductor layer 11 covers both the recesses 15 and the base surface 16, the contact area between the sapphire substrate 11 and the semiconductor layer 11 increases, and therefore, the dislocation density therebetween increases. Consequently, the internal quantum efficiency of the semiconductor light-emitting device 10 is lowered due to high dislocation density, and the external quantum efficiency thereof is affected at the same time.

Referring to FIG. 3, U.S. Pat. No. 6,091,083 discloses a gallium nitride type compound semiconductor light-emitting device having a buffer layer with non-flat surface, wherein a plurality of adjacent V-shaped grooves 33 are provided by etch process on a part of the surface of the sapphire substrate 31. A buffer layer 34, an N-type gallium nitride type compound semiconductor layer 35, an undoped gallium nitride type compound semiconductor layer 36 and an AlGaN (aluminum gallium nitride) layer 37 are formed on the sapphire substrate 31. The portion of the undoped gallium nitride type compound semiconductor layer 36 on the V-shaped grooves 33 has lower electrical resistance, while the planar area 32 has higher electrical resistance, and therefore, the undoped gallium nitride type compound semiconductor layer 36 is an electrical current block layer so as to form a current block structure. Apparently, the V-shaped grooves 33 and the recesses 15 disclosed in FIG. 1 have different function and effect.

FIGS. 4A-4D are schematic diagrams illustrating an epitaxial process for fabricating a semiconductor light-emitting diode disclosed in U.S. Pat. No. 6,940,089. A plurality of convex portions 42 and concave portions 43 are formed on a substrate 41, and a mask layer 44 (silicon dioxide) is formed on the bottom surfaces of the concave portions 43. An AlGaN layer 45 is formed on the tops of the convex portions 42. Because the AlGaN layer 45, the formation of which starts from the tops of the convex portions 42, is grown vertically and laterally over the concave portions 43, the lateral growth over the concave portions 43 helps to minimize dislocation density and prevent the issue of the growth of linear defects. Finally, a detached flat AlGan layer 45′, which can be used as a substrate material, is formed by removing the substrate 41. Due to the mask layer 44, the AlGaN layer 45 cannot remain on the bottom surfaces of the concave portions 43, and consequently, the AlGaN layer 45 cannot be formed on the bottom surfaces.

FIGS. 5A-5F are schematic diagrams illustrating an epitaxial process for fabricating a semiconductor light-emitting diode disclosed in U.S. Pat. No. 7,071,495. A light trapping member layer 53 is initially formed on a substrate 51 by employing a patterned photoresist layer 52. The light trapping member layer 53 comprises a plurality of convex portions and is made of material (Al₂O₃) identical to that of the substrate 51. Next, an uneven buffer layer 54 is formed on both the substrate 51 and the light trapping member layer 53, thereby increasing the light extraction efficiency. Thus, more light generated by the active layer (not shown) above the uneven buffer layer 54 is emitted through the substrate 51. The disclosed process is suitable for a light-emitting diode having a flip-chip package structure. The fabrication of the light trapping member layer 53 employs photolithography process and etching process steps.

FIG. 6 is a perspective view illustrating the light-emitting device disclosed in U.S. Patent Publication No. 2006/0267025. A plurality of spaced apart cavities 62 are formed on the patterned surface 63 of a sapphire substrate 61. Due to the lateral epitaxial growth rate of an N-type GaN layer 64 larger than the longitudinal epitaxial growth rate thereof, the N-type GaN layer 64 growing from a base surface gradually extends over the openings of the cavities 62. Simultaneously, the N-type GaN layer 64 growing upward from the inside surfaces of the cavities joins eventually the N-type GaN layer 64 growing along the base surface, and after joining, the N-type GaN layer 64 continues growing vertically until an N-type GaN layer 64 with a flat surface is formed. Although the line defects of the part of the n-GaN layer 64 formed on the patterned surface 63 are prevented from extending upward due to the lateral growth thereof, the middle line defects 65 of the part of the N-type GaN layer 64 formed on the surface of the cavities 62 still extend upward and result in the decrease of light emitting efficiency.

In conclusion, the market requires a light-emitting diode with guaranteed, stable quality and high light extraction efficiency, without the above-mentioned disadvantages.

### SUMMARY OF THE INVENTION

The primary aspect of the present invention is to provide a light-emitting device of Group III nitride-based semiconductor and manufacturing method thereof. Due to lateral growth of the Group III nitride formed directly on a substrate, threading dislocations can be suppressed, and therefore the light extraction efficiency of the light-emitting device can be increased.

In order to achieve the above aspect, the present invention proposes a light-emitting device of Group III nitride-based semiconductor, which comprises a substrate, a first Group III nitride layer and a second Group III nitride layer. The substrate comprises a first surface and a plurality of convex portions protruding from the first surface. Each convex portion is surrounded by a part of the first surface. The first Group III nitride layer is overlaid on the tops of the plurality of convex portions, and is jointly formed by lateral growth starting at the top surfaces of the convex portions. The second Group III nitride layer is formed on the first surface, and the thickness of the second Group III nitride layer is less than the height of the convex portion. Moreover, the first Group III nitride layer and the second Group III nitride layer are made of the same material.

When the first Group III nitride layer is a buffer layer, the light-emitting device of the present invention further comprises an N-type semiconductor layer, an active layer and a P-type semiconductor layer, wherein the N-type semiconductor layer, the active layer and the P-type semiconductor layer are formed in sequence on the first Group III nitride layer.

When the first Group III nitride layer is an N-type semiconductor layer, the light-emitting device of the present invention further comprises an active layer and a P-type semiconductor layer, wherein the active layer and the P-type semiconductor layer are formed in sequence on the first Group III nitride layer.

The substrate is a sapphire substrate; the first surface is a c-face of the sapphire substrate, wherein the c-face is (0001) face. The convex portions may be disposed along a direction matching with at least one of ( 1̅ 1̅ 2 0), (1 1 2̅ 0), ( 2̅ 1 1 0), (2 1̅ 1̅ 0), ( 1̅ 2 1̅ 0) and (1 2̅ 1 0) surfaces, or the convex portions may be disposed at equal distance along a direction matching with at least one of ( 1̅ 1̅ 2 0), (1 1 2̅ 0), ( 2̅ 1 1 0), (2 1̅ 1̅ 0), ( 1̅ 2 1 0) and (1 2̅ 1 0) surfaces in parallel.

The substrate can be formed of a material comprising sapphire, silicon carbide (SiC), silicon, zinc oxide (ZnO) or another material having a hexagonal crystal structure.

The present invention proposes a method for manufacturing a light emitting device of Group III nitride-based semiconductor, which comprises the steps of: providing a substrate, wherein the substrate comprises a first surface and a plurality of convex portions protruding from the first surface; each convex portion being surrounded by a part of the first surface; and forming a Group III nitride layer on the first surface and top surfaces of the convex portions, wherein the first Group III nitride layer on the top surfaces are jointly formed by lateral growth starting at the top surfaces of the convex portions; the thickness of the first Group III nitride layer on the first surface is less than the height of the convex portion.

When the first Group III nitride layer is a buffer layer, the method of the present invention further comprises the step of forming an N-type semiconductor layer, an active layer and a P-type semiconductor layer in sequence on the Group III nitride layer.

When the first Group III nitride layer is an N-type semiconductor layer, the method of the present invention further comprises the step of forming an active layer and a P-type semiconductor layer in sequence on the Group III nitride layer.

The first surface below the convex portions is fabricated using a photolithography process.

### BRIEF DESCRIPTION OF THE DRAWINGS

The invention will be described according to the appended drawings in which:

FIG. 1 is a cross sectional view illustrating a semiconductor light-emitting device disclosed in U.S. Pat. No. 6,870,191;

FIGS. 2A-2F are schematic diagrams illustrating an epitaxial process for forming an N-type semiconductor layer of FIG. 1 on a sapphire substrate;

FIG. 3 is a cross sectional view illustrating a semiconductor light-emitting device disclosed in U.S. Pat. No. 6,091,083;

FIGS. 4A-4D are schematic diagrams illustrating an epitaxial process for fabricating a semiconductor light-emitting diode disclosed in U.S. Pat. No. 6,940,089;

FIGS. 5A-5F are schematic diagrams illustrating an epitaxial process for fabricating a semiconductor light-emitting diode disclosed in U.S. Pat. No. 7,071,495;

FIG. 6 is a perspective view illustrating the light-emitting device disclosed in U.S. Patent Publication No. 2006/0267025;

FIG. 7A is a cross sectional view illustrating a light-emitting device of Group III nitride-based semiconductor according to one embodiment of the present invention;

FIG. 7B is a cross sectional view illustrating a light-emitting device of Group III nitride-based semiconductor according to another embodiment of the present invention;

FIG. 8A is a perspective view of a substrate according to one embodiment of the present invention;

FIG. 8B is a cross sectional view of a substrate according to one embodiment of the present invention;

FIG. 8C is a top view of the substrate according to one embodiment of the present invention;

FIGS. 9A-9D are schematic diagrams illustrating a process for fabricating a light-emitting device of Group III nitride-based semiconductor according to one embodiment of the present invention;

FIG. 10 shows curves of the output power of a light-emitting device of Group III nitride-based semiconductor according to one embodiment of the present invention and of a prior art device; and

FIGS. 11A-11B are X-ray diagrams of a light-emitting device of Group III nitride-based semiconductor according to one embodiment of the present invention and of a prior art device.

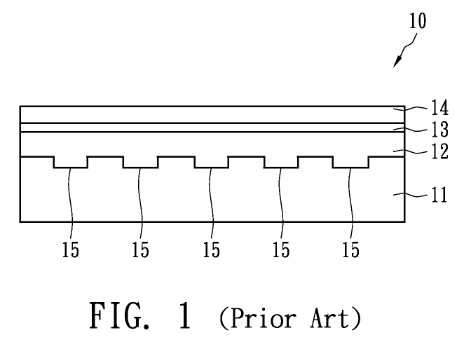

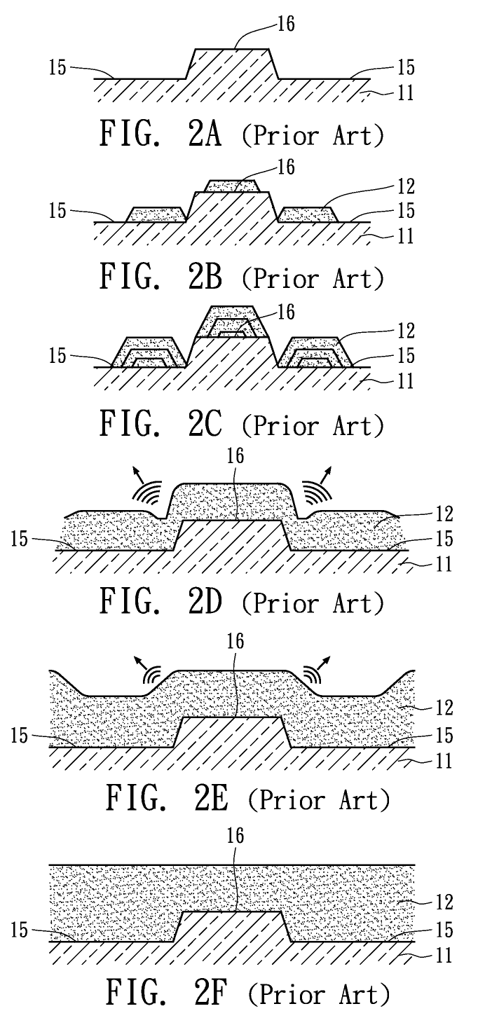

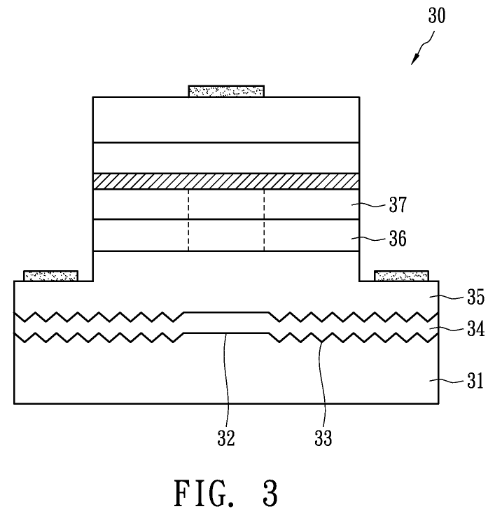

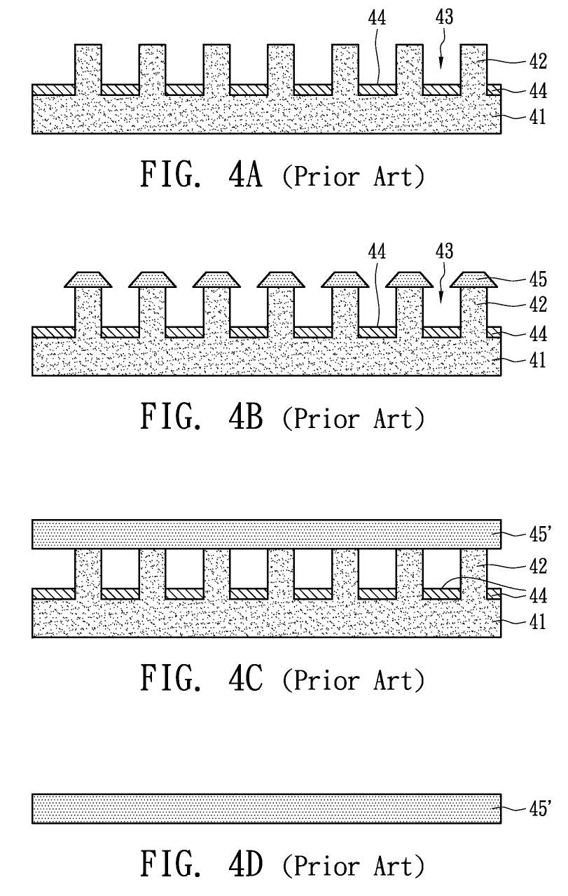

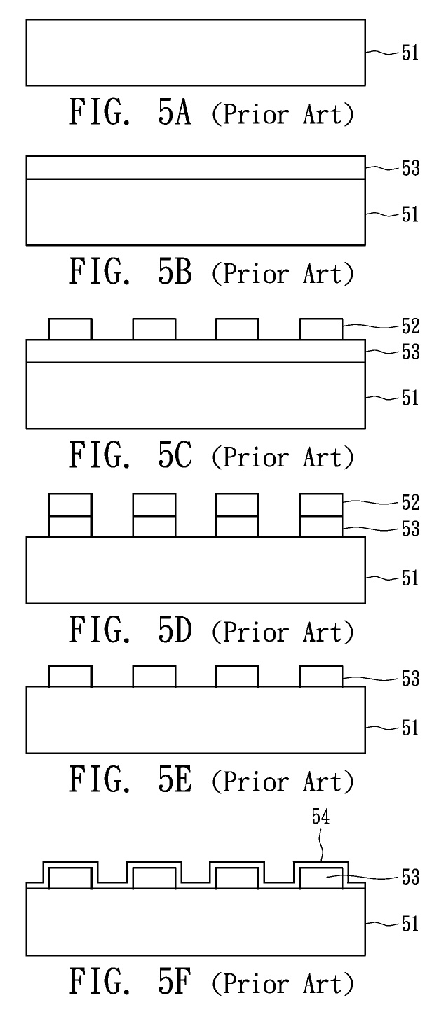

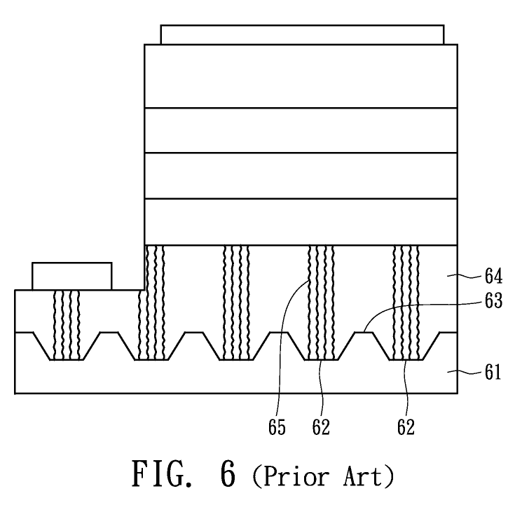

### DETAILED DESCRIPTION OF THE INVENTION

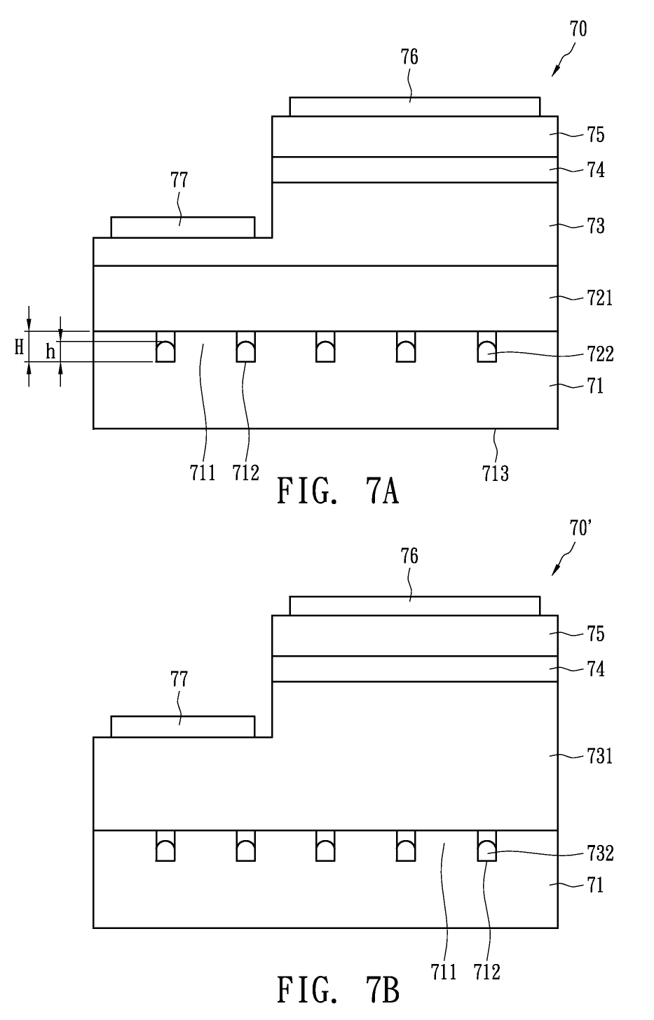

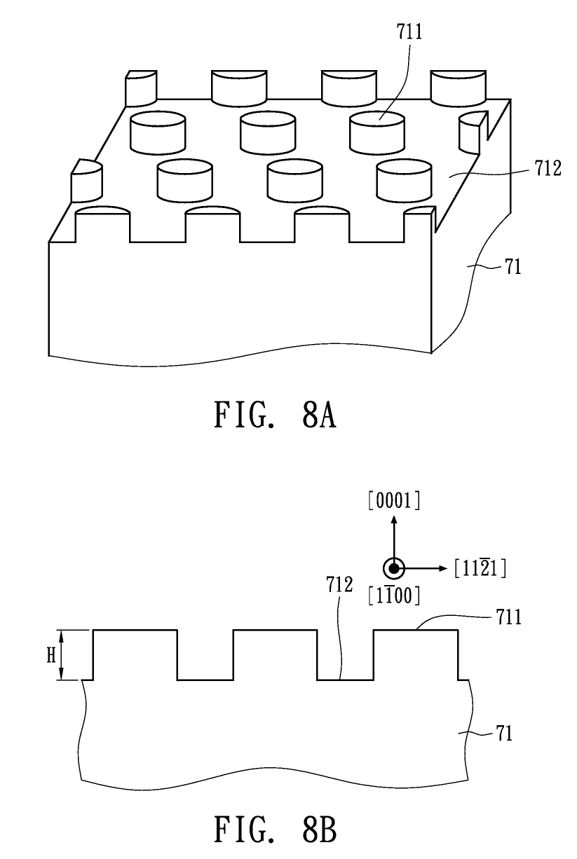

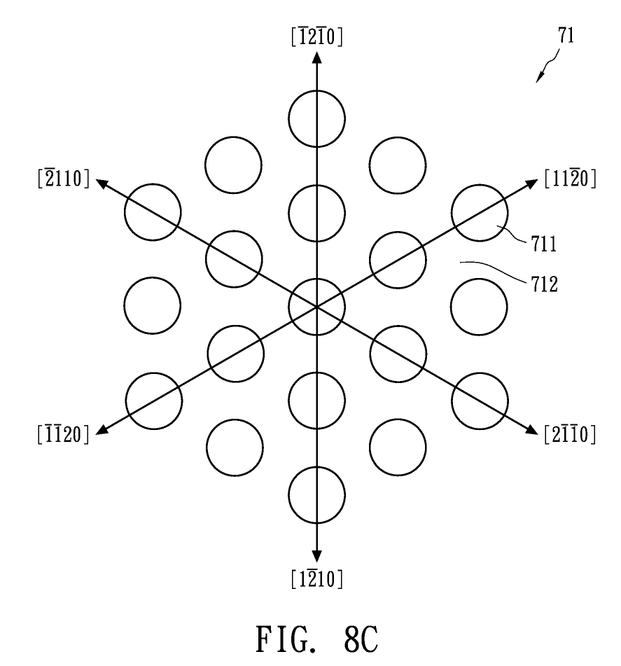

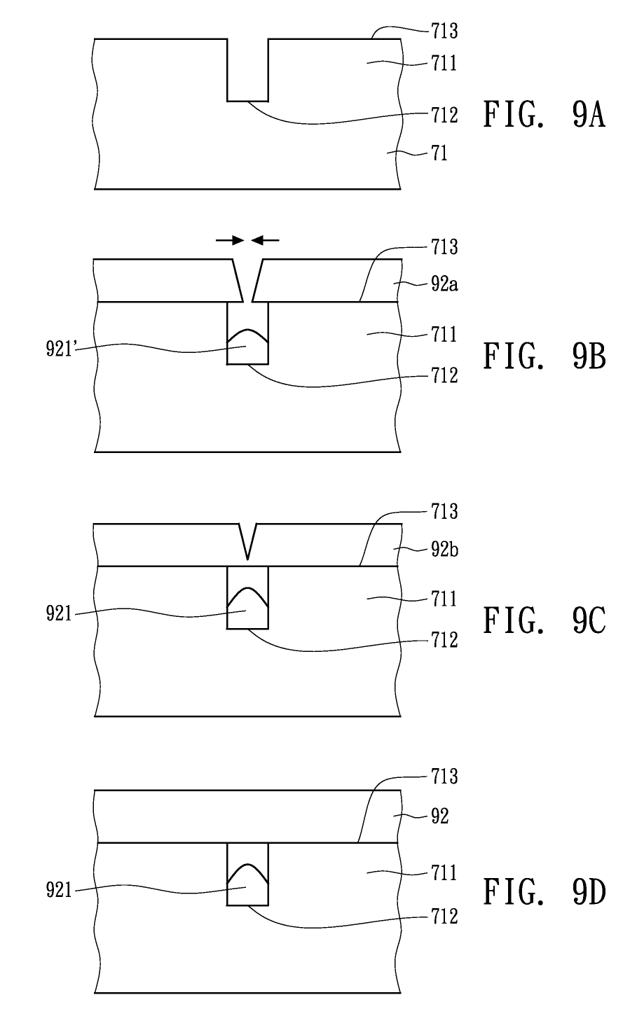

FIG. 7A is a cross sectional view illustrating a light-emitting device of Group III nitride-based semiconductor according to one embodiment of the present invention. The light-emitting device 70 comprises a substrate 71, a first buffer layer 721, a second buffer layer 722, an N-type semiconductor layer 73, an active layer 74 and a P-type semiconductor layer 75. Moreover, an N-type electrode 77 is formed on the N-type semiconductor layer 73 and a P-type electrode 76 is formed on the P-type semiconductor layer 75. The substrate 71 comprises a first surface 712, a plurality of convex portions 711 protruding from the first surface 712 and a second surface 713 opposite to the first surface 712. Each convex portion 711 is surrounded by a part of the first surface 712 as shown in FIG. 8(a).

The first buffer layer 721 is initially provided on the top surfaces of the convex portions 711, then extends laterally from these top surfaces, and finally connects mutually. The second buffer layer 722 is provided to cover the first surface 712 and has a thickness, h, less than the height, H, of the convex portion 711. Additionally, the first buffer layer 721 and the second buffer layer 722 can be made of the same material. The N-type semiconductor layer 73, the active layer 74 and the P-type semiconductor layer 75 are formed in sequence on the first buffer layer 721.

Generally, the substrate 71 is formed of material comprising sapphire (aluminum oxide, Al₂O₃), silicon carbide (SiC), silicon, zinc oxide (ZnO) and another material having a hexagonal crystal structure. Different Group III nitrides can be disposed on the substrate 71. If the lattice constants of the substrate 71 and the disposed Group III nitride are mismatched, a first buffer layer 721 can be formed on the substrate 71 before the Group III nitride is disposed. The first buffer layer 721 can be made of a material comprising GaN, InGan and AlGan. The first buffer layer 721 can also be a superlattice layer, which has hardness lower than the hardness of prior art buffer layers containing aluminum.

Referring to FIG. 7B, the first surface 712 of the substrate 71 and the top surfaces of the convex portions 711 are respectively provided with N-type semiconductor layers 731 and 732. Similarly, an active layer 74 and a P-type semiconductor layer 75 are formed in sequence on the N-type semiconductor layer 731, and therefore a light-emitting device 70′ having an epitaxial growth structure is fabricated.

FIG. 8A is a perspective view of a substrate according to one embodiment of the present invention. A plurality of convex portions 711 protrude from the first surface 712. Each convex portion 711 is surrounded by a part of the first surface 712. The first surface 712 below the convex portions 711 can be fabricated using a photolithography process. FIG. 8B is a cross sectional view of the substrate 71 according to one embodiment of the present invention. The substrate 71 can be a c-face (0001) sapphire substrate. As a result, the first buffer layer 721 formed on the sapphire substrate contains no lattice defects. FIG. 8C is a top view of the substrate 71 according to one embodiment of the present invention. A plurality of convex portions can be disposed along the direction matching with at least one of the ( 1̅ 1̅ 2 0), (1 1 2̅ 0), ( 2̅ 1 1 0), (2 1̅ 1̅ 0), ( 1̅ 2 1̅ 0) and (1 2̅ 1 0) surfaces. A plurality of convex portions can also be disposed at equal distance along the direction matching with at least one of the ( 1̅ 1 2 0), (1 1 2̅ 0), ( 2̅ 1 1 0), (2 1̅ 1̅ 0), ( 1̅ 2 1̅ 0) and (1 2 1 o) surfaces in parallel.

FIGS. 9A-9D are schematic diagrams illustrating a process for fabricating a light-emitting device of Group III nitride-based semiconductor according to one embodiment of the present invention. The Group III nitride layer 92a provided to cover the top surface 713 of each convex portion 711 grows laterally toward the top surfaces 713 of the adjacent convex portions 711 gradually. At the same time, the Group III nitride 921′ layer provided to cover the first surfaces 712 grows gradually to cover the first surfaces 712 and then grows upward and toward the respective middle areas between pairs of adjacent top surfaces 713. Both the Group III nitride layers 92a and the Group III nitride layer 921′ grow simultaneously. As shown in FIG. 9C, the Group III nitride layer 921′ formed on a first surface 712 is shielded and does not grow further because the Group III-nitride layers 92a formed on the top surfaces of the convex portions 711 located beside the first surface 712 join together. Moreover, both the Group III nitride layer 92a and the Group III nitride layer 921′ will not join together. The disclosed process can be continued to obtain a Group III nitride layer 92 with a flat surface.

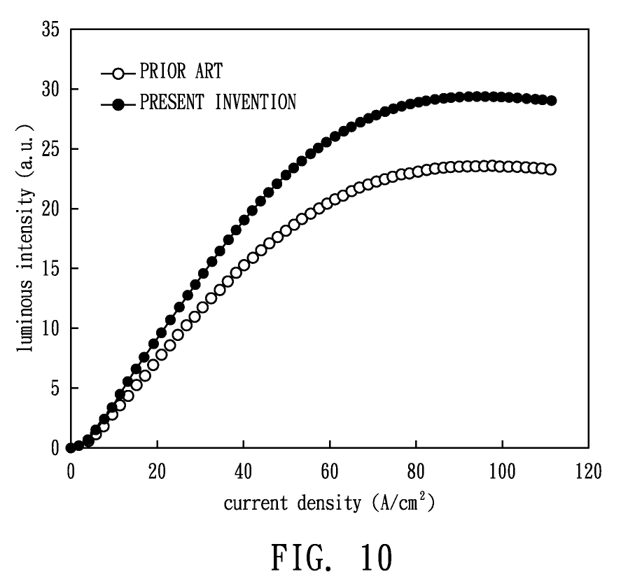

FIG. 10 shows curves of the output power of a light-emitting device of Group III nitride-based semiconductor according to one embodiment of the present invention and of a prior art device. Compared to prior art light-emitting devices, the light-emitting device of Group III nitride-based semiconductor of the present invention can attain higher luminous intensity when the same current density is used to apply thereto. As a result, the light-emitting device of Group III nitride-based semiconductor of the present invention has better light-emitting efficiency.

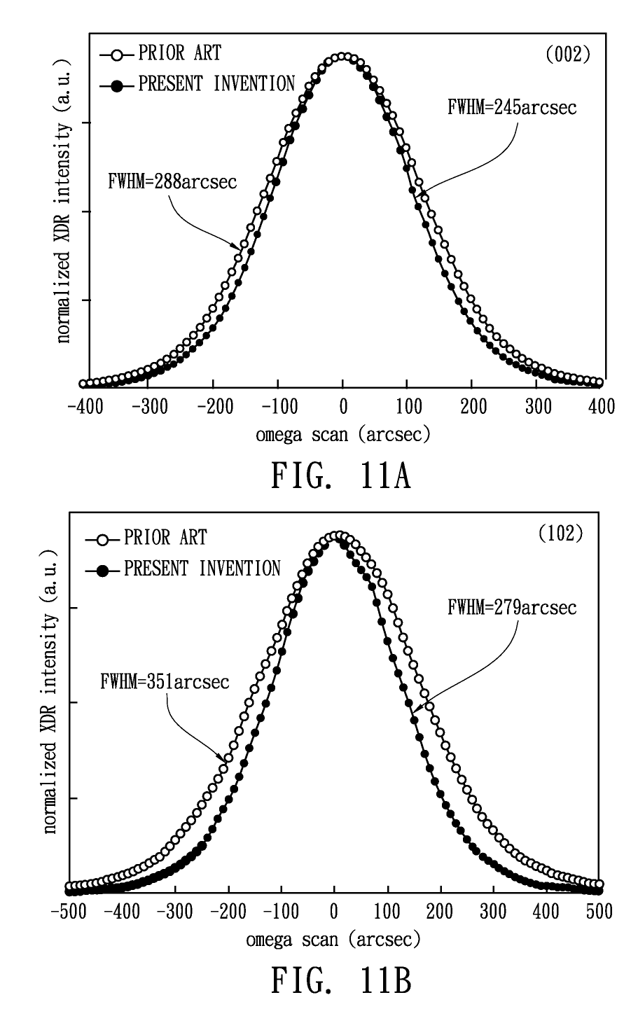

FIGS. 11A-11B are X-ray diagrams of a light-emitting device of Group III nitride-based semiconductor according to one embodiment of the present invention and of a prior art device. The X-ray diagrams of the prior art device shown in FIGS. 11A-11B are measured from a light-emitting device which uses a substrate with planar shape. According to the X-ray diffraction measurement of the light-emitting device of Group III nitride-based semiconductor of the present invention, the standardized full width at half maximum (FWHM) of the curves corresponding to diffraction for (002) and (102) planes are all narrower, as compared to the prior art device.

The above-described embodiments of the present invention are intended to be illustrative only. Numerous alternative embodiments may be devised by persons skilled in the art without departing from the scope of the following claims.

What is claimed is:

1. A light-emitting device of Group III nitride-based semiconductor, comprising:
a substrate comprising a first surface and a plurality of convex portions protruding from the first surface; each of the convex portions surrounded by a part of the first surface;
a first Group III nitride layer jointly formed by lateral growth starting at top surfaces of the convex portions; and
a second Group III nitride layer formed on the first surface, wherein the thickness of the second Group III nitride layer is less than the height of the convex portion.

2. The light-emitting device of claim 1, wherein the first Group III nitride layer and the second Group III nitride layer are made of a same material.

3. The light-emitting device of claim 1, wherein the first Group III nitride layer is a buffer layer.

4. The light-emitting device of claim 3, further comprising an N-type semiconductor layer, an active layer and a P-type semiconductor layer, wherein the N-type semiconductor layer, the active layer and the P-type semiconductor layer are formed in sequence on the first Group III nitride layer.

5. The light-emitting device of claim 1, wherein the first Group III nitride layer is an N-type semiconductor layer.

6. The light-emitting device of claim 5, further comprising an active layer and a P-type semiconductor layer, wherein the active layer and the P-type semiconductor layer are formed in sequence on the first Group III nitride layer.

7. The light-emitting device of claim 1, wherein the substrate is a sapphire substrate, and the first surface is a c-face of the sapphire substrate, wherein the c-face is (0001) face.

8. The light-emitting device of claim 7, wherein the convex portions are disposed along a direction matching with at least one of ( 1̅ 1̅ 2 0), (1 1 2̅ 0), ( 2̅ 1 1 0), (2 1̅ 1̅ 0), ( 1̅ 2 1̅ 0) and (1 2̅ 1 0) surfaces.

9. The light-emitting device of claim 7, wherein the convex portions are disposed at equal distance along a direction matching with at least one of ( 1̅ 1̅ 2 0), (1 1 2̅ 0), ( 2̅ 1 1 0), (2 1̅ 1̅ 0), ( 1̅ 2 1̅ 0) and (1 2̅ 1 0) surfaces in parallel.

10. The method of claim 1, wherein the substrate is formed of a material comprising sapphire, silicon carbide, silicon, zinc oxide and a material which has a hexagonal crystal structure.

11. A method for manufacturing a light emitting device of Group III nitride-based semiconductor, comprising steps of:
providing a substrate, wherein the substrate comprises a first surface and a plurality of convex portions protruding from the first surface, and each of the convex portions surrounded by a part of the first surface; and
forming a Group III nitride layer on the first surface and top surfaces of the convex portions, wherein the first Group III nitride layer on the top surfaces are jointly formed by lateral growth starting at the top surfaces of the convex portions; the thickness of the first Group III nitride layer on the first surface is less than the height of the convex portion.

12. The method of claim 11, wherein the Group III nitride layer is a buffer layer.

13. The method of claim 12, further comprising the step of forming an N-type semiconductor layer, an active layer and a P-type semiconductor layer in sequence on the Group III nitride layer.

14. The method of claim 11, wherein the Group III nitride layer is an N-type semiconductor layer.

15. The method of claim 14, further comprising the step of forming an active layer and a P-type semiconductor layer in sequence on the Group III nitride layer.

16. The method of claim 11, wherein the substrate is a sapphire substrate; the first surface is a c-face of the sapphire substrate, wherein the c-face is (0001) face.

17. The method of claim 16, wherein the convex portions are disposed along a direction matching with at least one of ( 1̅ 1̅ 2 0), (1 1 2̅ 0), ( 2̅ 1 1 0), (2 1̅ 1̅ 0), ( 1̅ 2 1̅ 0) and (1 2̅ 1 0) surfaces.

18. The method of claim 16, wherein the convex portions are disposed at equal distance along a direction matching with at least one of ( 1̅ 1̅ 2 0), (1 1 2̅ 0), ( 2̅ 1 1 0), (2 1̅ 1̅ 0), ( 1̅ 2 1̅ 0) and (1 2̅ 1 0) surfaces in parallel.

19. The method of claim 11, wherein the substrate is formed of a material comprising sapphire, silicon carbide, silicon, zinc oxide and a material which has a hexagonal crystal structure.

20. The method of claim 11, wherein the first surface below the convex portions is fabricated using a photolithography process.
